(19) United States
(12) Patent Application Publication
(10) Pub. No.: US 2010/0065418 A1
(43) Pub. Date: Mar. 18, 2010

(54) REACTIVE MAGNETRON SPUTTERING FOR THE LARGE-SCALE DEPOSITION OF CHALCOPYRITE ABSORBER LAYERS FOR THIN LAYER SOLAR CELLS

(75) Inventors: Klaus Ellmer, Berlin (DE); Thomas Unold, Potsdam (DE)

Correspondence Address: DARBY & DARBY P.C., P.O. BOX 770, Church Street Station, New York, NY, 10008-0770, US

(73) Assignee: Helmholtz-Zentrum Berlin fuer Materialien und Energie GmbH, Berlin (DE)

(21) Appl. No.: 12/516,713

(22) PCT Filed: Nov. 7, 2007
(86) PCT No.: PCT/DE07/01998

§ 371 Date: May 28, 2009

(30) Foreign Application Priority Data
Nov. 29, 2006 (DE) 10 2006 057 068.5

(51) Int. Cl. C23C 14/35; C23C 14/54

(52) U.S. Cl. 204/192.13; 204/192.28

(57) ABSTRACT

A method of reactive magnetron sputtering for large-area deposition of a chalcopyrite absorber layer for thin-film solar cells on a substrate, using at least one magnetron sputter source with at least one copper target, and using an inert gas and a chalcogen-containing reactive gas in a magnetron plasma, includes introducing the chalcogen-containing reactive gas directly at the substrate. The chalcogen-containing reactive gas fraction is set at 5 to 30% of the inert gas fraction in the magnetron plasma. A sputtering pressure of between 1 and 2 Pa, is set. A negative bias voltage is applied to the substrate. The magnetron plasma is excited by rapid frequency AC voltage above 6 MHz. The substrate is heated to a temperature between 350° C. and 500° C. Low-copper deposition is performed by disposing different targets serially in the at least one magnetron sputter source and operating the targets at the same sputtering power, or by disposing same targets in the at least one magnetron sputter source and operating the targets at different sputtering powers so as to obtain stoichiometry gradients.

### CROSS REFERENCE TO PRIOR APPLICATIONS

This application is a U.S. National Phase application under 35 U.S.C. §371 of International Application No. PCT/DE2007/001998, filed on Nov. 7, 2007 and claims benefit to German Patent Application No. DE 10 2006 057 068.5, filed on Nov. 29, 2006. The International Application was published in German on Jun. 5, 2008 as WO 2008/064632 under PCT Article 21(2).

### FIELD

The present invention relates to reactive magnetron sputtering for large-area deposition of chalcopyrite absorber layers in thin-film solar cells.

### BACKGROUND

The photovoltaics industry is currently growing at very high rates of 30 to 40% per annum. But as compared to solar cells of crystalline silicon, thin-film solar cells make up only about 5 percent of the market. However, thin-film technology has a number of attractive advantages, such as the possibility of coating large surfaces at low cost, the coating of flexible substrates, and the potential implementation of complete continuous-coating or even roll-to-roll solar cell coating systems (coil coating). Magnetron sputtering is a deposition method which is particularly suited for coating large surfaces. Every year, a surface on the order of 50-100 millions of square meters of architectural and thermally insulating glass in sizes of up to 3×6 m is coated using this method. In industrial-scale applications, magnetron sputtering is today used mainly in the production of metal layers (compact discs, microelectronics), optical layers (such as antireflective coatings, thermal insulation layers), magnetic layers (hard disks, read heads), hard material layers (tool coating) and protective layers (SiO₂). This wide range of applications suggests that magnetron sputtering is a deposition technique that should also be particularly suitable for large-area manufacture of solar cells.

A thin-film solar cell is basically very simple in construction. An absorber layer (e.g., a highly absorptive compound semiconductor) is deposited as an active layer on a metallic back contact (e.g., molybdenum). In addition, in order to allow light entry and current collection, a transparent front contact is needed, said transparent front contact being made of a degenerate broad-band semiconductor (e.g., indium-tin oxide or zinc oxide). Usually, a buffer layer is inserted between the absorber and the window layer so as to improve the interfacial properties, and thus, the open circuit voltage of the solar cell. A layered structure as simple as this and having an overall thickness ranging from 2-4 μm should be particularly suitable for a continuous coating process, such as magnetron sputtering. While today, the metal layer and the oxidic window layer are already manufactured by magnetron sputtering, this process technology has not yet been adopted for the absorber layers. Although in the prior art, attempts have repeatedly been made to deposit highly absorptive compound semiconductors (e.g., CdTe, CuInSe₂, CuInS₂) directly by magnetron sputtering (Ellmer, K., et al., “Copper Indium Disulfide Solar Cell Absorbers Prepared in a One-Step Process by Reactive Magnetron Sputtering From Copper and Indium Targets” Thin Solid Films, (2002) 413 (1-2), 92-97), large-area and/or roll-to-roll processes are successfully used for amorphous silicon (Uni-Solar). The active a-Si:H layer is formed using plasma-enhanced chemical vapor deposition (PECVD) at excitation frequencies that exceed 13 MHz and substrate temperatures of about 250° C.

However, compared to thin-film solar cells manufactured using thermal deposition or vapor deposition processes, the solar cells produced in the aforementioned manner using amorphous silicon have a relatively low efficiency of about 6% because of the inherent, light-induced degradation of this material. However, an efficiency of 10% is considered necessary by the industry to be able to establish a thin-film solar cell technology on the market.

Solar cell efficiencies greater than 10% were heretofore only achievable in sputtering processes using co-evaporation and including additional annealing steps at higher temperatures, either in a CdCI₄ atmosphere in the case of CdTe solar cells, or by sulfurization in the case of CuInS₂, or by means of a sputter process followed by a selenization step. However, it is difficult to scale-up evaporation and selenization processes. Moreover, continuous roll-to-roll processes for this procedure are not known in the prior art.

Roll-to-roll sputtering process using CuSe₂ and InGaSe compound targets are described, for example, in patent documents U.S. Pat. No. 6,974,976 B2, U.S. 2004/0063320 A1 and U.S. 2005/0109392 A1. However, these patent documents only describe the arrangement and/or the materials of the layers of the solar cell. The specifics of the magnetron sputtering process (thermalization of sputtered species, particle energies, chemical activation) are not discussed therein.

CuInS₂ thin-film solar cells are commercially manufactured using a process in which metallic precursor layers are sputtered and subsequently sulfurized (DE 100 04 733 C2). However, this is only possible in Cu-rich processes, in which the highly conductive CuₓS phases formed are subsequently etched away in a highly toxic KCN solution. Other typical deposition requirements include substrate temperatures of 500 to 550° C. and a significant excess of sulfur for the sulfurization reaction.

A roll-to-roll solar cell coating process has also not been demonstrated in using the conventional processing procedure for CuInS₂ thin-film solar cells. Furthermore, the sequential process does not allow the controlled creation of chemical gradients across the thickness of the chalcopyrite absorber layer, because the layers are completely intermixed during thermal sulfurization or selenization, so that previously created gradients would be eliminated. Experiments on RF sputtering and on reactive magnetron sputtering of CuInS₂ have been carried out over the last 20 years, but without achieving a stable process with efficiencies comparable to those of solar cells produced by established processes (Lommasson, T., “Magnetron Reactive Sputtering of Copper-Indium-Selenide”, Solar Cells (1986), 16, 165-180). These failures have led many in the photovoltaics community to believe that magnetron sputtering can indeed be used for contact layers (molybdenum and/or ZnO/ZnO:AI) and for precursor layers (Cu, In), but not for the deposition of active layers; i.e., of solar cell absorbers, because these must particularly stringent requirements in terms of defect density (Romeo, A, et al., “Development of thin-film Cu(In,Ga)Se2 and CdTe solar cells”, Prog. Photovolt: Res. Appl. (2004) 12, 93-111).

When using reactive magnetron sputtering for hard material layers, metal layers, or optical layers, current state-of-the-art methods use substrate bias voltages of −100 to −300 V relative to the plasma potential so as to increase the ion contribution to the layer growth. Moreover, for some years, heavy-duty sputtering power supplies are used which apply voltages far above 1,000 volts to the magnetron sputtering target during brief periods of time so as to provide high-energy particles for layer growth.

In a magnetron sputtering discharge, a plurality of ions and neutral particles having energies ranging from several to several hundred electron volts (eV) are present in the plasma. These energies are much higher than those occurring in a purely thermal deposition process, and also much higher than the damage energies in semiconductors, which are usually in the range of several eV. They increase the adatom mobility on the growing layer, thereby improving the morphology and crystalline quality thereof. However, the continuous particle bombardment of the growing film surface also produces structural and, thus, electronic defects in the layer. The number of defects produced is highly dependent on the selected material system and on the interaction of the selected sputtering parameters, such as temperature, pressure and power density. In the case of optical, metallic, magnetic or hard material layers, a well controlled composition, thickness homogeneity, and in some cases, the crystalline quality are important, whereas in the case of photoactive semiconductor layers, the electronic properties, in particular the number of electronic defects, are decisive. In order to achieve efficiencies above 10% in thin-film solar cells, the diffusion lengths of the photogenerated charge carriers must be on the order of the layer thickness, which is equivalent to a concentration of the electronic defects in the ppm range. On the other hand, due to the higher particle energies and the presence of chemically reactive components (atomic and excited species), plasma-based deposition methods make it possible to produce layers at significantly lower substrate temperatures, or to produce more compact layers, which is particularly attractive for the manufacture of thin-film solar cells. In the prior art, it has already been shown that reactive magnetron sputtering is suitable for the deposition of high-quality CuInS₂ layers if the coating parameters are specially selected with respect to the particle energies during layer growth. Solar cells made from such material achieve efficiencies of more than 10%, which are comparable to those of thermally processed CuInS₂ layers (K. Ellmer, K. et al., “Copper indium disulfide solar cell absorbers prepared in a one-step process by reactive magnetron sputtering from copper and indium targets” Thin Solid Films (2002) 413 (1-2), 92-97; Unold, T., et al., “CuInS₂ Absorber Layers and Solar Cells Deposited by Reactive Magnetron Sputtering from Metallic Targets”, Paris, France, Jun. 7-11, 2004 (WIP-Munich and ETA-Florence), 1917-1920; Unold, T. et al., “Optical, Structural and Electronics Properties of CuInS₂ Solar Cells Deposited by Reactive Magnetron Sputtering”, Mat. Res. Soc. Symp. Proc. (2005) 865, F16.5.1-16.5.6; Unold, T. et al., “Reactive Magnetron Sputtering of CuInS₂ Solar Cells—The Influence of the Deposition Conditions on Structural and Electronic Properties and Solar Cell Efficiency”, PVSEC-15, Shanghai, China, Oct. 10-15, 2005, Shanghai Sci. Techn. Publ., 503-504; Unold, T. et al., “Efficient CuInS₂ solar cells by reactive magnetron sputtering”, Appl. Phys. Lett. (2006) 88 (21), 213502-213505; Unold, T., et al., “Reaktives Magnetronsputtern von Dünnschichtsolarzellen” [Reactive Magnetron Sputtering of Thin Film Solar Cells], Vakuum in Forschung und Praxis [Vacuum in Research and Practice] (2006), 18:5, 6-10).

The prior art demonstrates that suitable selection of the material system and optimized sputtering conditions, allows for the production of thin-film semiconductors with good electronic properties (Ellmer, K. et al., “Copper Indium Disulfide solar cell absorbers prepared in a one-step process by reactive magnetron sputtering from copper and indium targets” Thin Solid Films (2002) 413 (1-2), 92-97; Romeo, A. et al., “Development of Thin-Fil Cu(In,Ga)Se₂ and CdTe solar cells”, Prog. Photovolt: Res. Appl. (2004) 12, 93-111; Unold, T., et al., “CuInS₂ Absorber Layers and Solar Cells Deposited by Reactive Magnetron Sputtering from Metallic Targets”, Paris, France, Jun. 7-11, 2004 (WIP-Munich and ETA-Florence), 1917-1920; Unold, T. et al., “Optical, Structural and Electronics Properties of CuInS₂ Solar Cells Deposited by Reactive Magnetron Sputtering”, Mat. Res. Soc. Symp. Proc. (2005) 865, F16.5.1-16.5.6; Unold, T. et al., “Reactive Magnetron Sputtering of CuInS₂ Solar Cells—The Influence of the Deposition Conditions on Structural and Electronic Properties and Solar Cell Efficiency”, PVSEC-15, Shanghai, China, Oct. 10-15, 2005, Shanghai Sci. Techn. Publ., 503-504; Unold, T. et al., “Efficient CuInS₂ solar cells by reactive magnetron sputtering”, Appl. Phys. Lett. (2006) 88 (21), 213502-213505; Unold, T., et al., “Reaktives Magnetronsputtern von Dünnschichtsolarzellen”[Reactive Magnetron Sputtering of Thin Film Solar Cells], Vakuum in Forschung und Praxis [Vacuum in Research and Practice] (2006), 18:5, 6-10). However, until now, this was limited to copper-rich deposition of CuInS₂ and was based on a substrate temperature setting higher than 470° C. To date, the prior art has not provided a method of depositing absorber layers which are suitable for solar cells, which can be deposited at temperatures below 470° C., and which need not be subjected to subsequent chemical steps. The reason for this is that no technique has yet been found to prevent bombardment of the growing layer by high-energy particles while at the same time making use of a suitable low-energy input from the particles to allow for low substrate temperatures. Furthermore, it has heretofore not been possible to deposit low-copper layers, because it was impossible to incorporate a sufficient number of copper atoms into such layers.

### SUMMARY

In an embodiment, the present invention provides a method of reactive magnetron sputtering for large-area deposition of a chalcopyrite absorber layer for thin-film solar cells on a substrate, using at least one magnetron sputter source with at least one copper target, and using an inert gas and a chalcogen-containing reactive gas in a magnetron plasma. The method includes introducing the chalcogen-containing reactive gas directly at the substrate. The chalcogen-containing reactive gas fraction is set at 5 to 30% of the inert gas fraction in the magnetron plasma. A sputtering pressure of between 1 and 2 Pa is set. A negative bias voltage is applied to the substrate. The magnetron plasma is excited by rapid frequency AC voltage above 6 MHz. The substrate is heated to a temperature between 350° C. and 500° C. Low-copper deposition is performed by disposing different targets serially in the at least one magnetron sputter source and operating the targets at the same sputtering power, or by disposing same targets in the at least one magnetron sputter source and operating the targets at different sputtering powers so as to obtain stoichiometry gradients.

### BRIEF DESCRIPTION OF THE DRAWINGS

FIG. 1 is an exemplary schematic cross-sectional view of a sputtering chamber showing the arrangement of the targets, the substrate, and the heater.

FIG. 2 illustrates the introduction of the reactive gas at the substrate.

FIG. 3 illustrates the introduction of the inert gas at the targets.

### DETAILED DESCRIPTION

The present invention provides magnetron sputtering for large-area deposition of chalcopyrite absorber layers in thin-film solar cells on a substrate, using a magnetron sputter source with at least one copper target, and using an inert gas and a chalcogen-containing reactive gas in the magnetron plasma. One aspect of the present invention relates to adjusting the process parameters in a way that makes it possible to use the advantages of magnetron sputtering, such as low substrate temperatures, large-area deposition, high chemical reactivity, compact layers for direct deposition of chalcopyrite absorber layers, while at the same time avoiding the disadvantages, including, in particular, damage to the sensitive semiconductor layers.

The inventive combination of parameters results from most recent and partly surprising discoveries made by the inventors using specific and detailed plasma diagnostic methods, which were also developed by the inventors and which revealed to the inventors a number of previously unknown properties exhibited by the chalcogen-containing reactive gas plasma in the magnetron sputtering process. New, previously unknown knowledge was gained about the behavior of the chalcogen-containing reactive gas, including of hydrogen chalcogenides, such as H₂S, in a sputtering plasma. The special excitation of the chalcogen-containing reactive gas by the magnetron sputter sources and the suitable selection of process parameters in accordance with the present invention together result in the preferential formation of small chalcogen molecules, such as sulfur molecules, in spite of moderate substrate temperatures of, for example, 370° C. This makes it possible, for the first time, to deposit, for example, In-rich layers by magnetron sputtering without requiring any additional chemical steps to be performed during subsequent processing in order to remove free chalcogens, in particular to remove excess sulfur. This new knowledge made it possible to minimize the negative properties of the reactive gas plasma known from the prior art by means of a specific skillful and partly surprising selection and combination of parameters and, at the same time, to retain the beneficial properties of the reactive gas plasma, thereby achieving the above-described object. In one embodiment of the invention, the resulting parameter combination for the sputtering process includes the following:
introducing the chalcogen-containing reactive gas directly at the substrate
setting the reactive gas fraction at 5 to 30% of the inert gas fraction in the magnetron plasma,
setting the sputtering pressure at a high value between 1 and 2 Pa
applying a negative bias voltage to the substrate
arranging different targets serially in the magnetron sputter sources and operating them at the same sputtering power, or arranging identical targets in the magnetron sputter source and operating them at different sputtering powers so as to obtain stoichiometry gradients
exciting the magnetron plasma by radio frequency AC voltage above 6 MHz
heating the substrate to a temperature between 350° C. and 500° C., and
performing low-copper deposition.

For the first time, the present invention provides, in a magnetron sputtering method, a combination of different parameters that allows large-area deposition of low defect density absorber layers in solar cells with efficiencies significantly higher than 10%. Here, in addition to the parameters of plasma excitation, substrate temperature, sputtering pressure, and low-copper deposition, which are known in the prior art and have already been varied (Ellmer, K. et al., “Copper Indium Disulfide solar cell absorbers prepared in a one-step process by reactive magnetron sputtering from copper and indium targets” Thin Solid Films (2002) 413 (1-2), 92-97; Unold, T., et al., “CuInS₂ Absorber Layers and Solar Cells Deposited by Reactive Magnetron Sputtering from Metallic Targets”, Paris, France, Jun. 7-11, 2004 (WIP-Munich and ETA-Florence), 1917-1920; Unold, T. et al., “Optical, Structural and Electronics Properties of CuInS₂ Solar Cells Deposited by Reactive Magnetron Sputtering”, Mat. Res. Soc. Symp. Proc. (2005) 865, F16.5.1-16.5.6; Unold, T. et al., “Reactive Magnetron Sputtering of CuInS₂ Solar Cells—The Influence of the Deposition Conditions on Structural and Electronic Properties and Solar Cell Efficiency”, PVSEC-15, Shanghai, China, Oct. 10-15, 2005, Shanghai Sci. Techn. Publ., 503-504; Unold, T. et al., “Efficient CuInS₂ solar cells by reactive magnetron sputtering”, Appl. Phys. Lett. (2006) 88 (21), 213502-213505; Unold, T., et al., “Reaktives Magnetronsputtern von Dünnschichtsolarzellen”[Reactive Magnetron Sputtering of Thin Film Solar Cells], Vakuum in Forschung and Praxis [Vacuum in Research and Practice] (2006), 18:5, 6-10), new parameters are presented and combined in an unexpected way. In one embodiment, these new parameters include the following:

Reactive gas fraction: The reactive gas fraction may range from 5 to 30% of the inert gas fraction so as to minimize the fraction of negative ions (e.g., S⁻, HS⁻, HS₂⁻) from the magnetron sputter source.

Reactive gas inlet: The chalcogen-containing reactive gas (e.g., H₂S) may be introduced directly at the substrate. In one embodiment, the reactive gas is applied parallel to the substrate surface, so as to prevent the formation of negative ions (S⁻ ions) at the target, which would be accelerated to high energies from the magnetron sputter source to the substrate.

Substrate bias voltage: During the sputtering process, a negative bias voltage may be applied to the substrate so as to impart a specific additional energy of between 20-50 eV to the thermalized, but ionized species upstream of the substrate (e.g., Ar⁺, Cu⁺, In⁺, S⁺, Se⁺). This makes it possible to deposit, for example, compact, low defect density semiconductor layers at low substrate temperatures.

Arrangement and operation of the targets: In one embodiment of the present invention, different targets are arranged serially in time and operated at the same sputtering power. In another embodiment, identical targets are arranged parallel in time and operated at different sputtering powers and, thus, at different deposition rates. In this manner, vertical element gradients (Ga, In, Cu, AI, and other) are created in the deposited layer.

In another embodiment, the present invention combines known parameters in an advantageous manner

Plasma excitation: The plasma may be excited by radio frequency above 6 MHz.

Substrate temperature: The substrate temperature can be set at moderate levels (preferably below 420° C.). Thus, flexible polymer films which do not withstand higher temperatures can also be used as substrates.

Sputtering pressure: Sputtering may be performed at relatively high pressures (above 1 Pa) so as to thermalize the particles and ions from the magnetron sputter source.

Deposition: The deposition performed includes low-copper deposition. When manufacturing CuInS₂ layers, this is equivalent to indium-rich deposition ([In]/[Cu]>1). This prevents the formation of excess CuₓS, thus eliminating the need for a wet-chemical etching step in toxic KCN, which is otherwise always needed to remove it. In one embodiment of the invention described herein, the low-copper deposition results in high-quality solar cell absorber layers when using, for example, the surprisingly found parameter combinations defined above.

Due to the aforementioned optimum combination of the various new and known sputtering parameters, the present invention makes it possible to use the advantages of magnetron sputtering (additional energy input) while avoiding the potential disadvantages (damage caused to the growing layer by ion bombardment). Moreover, the high chemical reactivity of the plasma is used to enable the necessary chalcogenization (e.g. by sulfur) of the metals (e.g., copper and indium) to be carried out at lower temperatures and without the otherwise usual excess of copper during layer deposition. Thus, it is possible, particularly in the case of sulfur-based chalcogenides, to eliminate the otherwise usual wet-chemical etching step, thereby considerably simplifying the manufacturing process of such thin-film solar cells.

In one embodiment, the present invention advantageously allows a graded band gap transition from the narrow-band chalcopyrite absorber layer to an adjacent buffer layer in the thin-film solar cells to be created by suitable selection of the target materials. For example, it is possible to sputter other elements (e.g., aluminum or zinc), or to dispense with an element (e.g., copper).

In another embodiment, the method of the present invention also makes it possible to implement process feedback by means of optical in situ-measurement, for example, by Raman spectroscopic phase analysis, and to vary the magnetron sputtering power and/or the substrate bias voltage according to the measured values.

The parameter-optimized magnetron sputtering according to the present invention will now be described in greater detail with reference to specific embodiments and the accompanying schematic drawings.

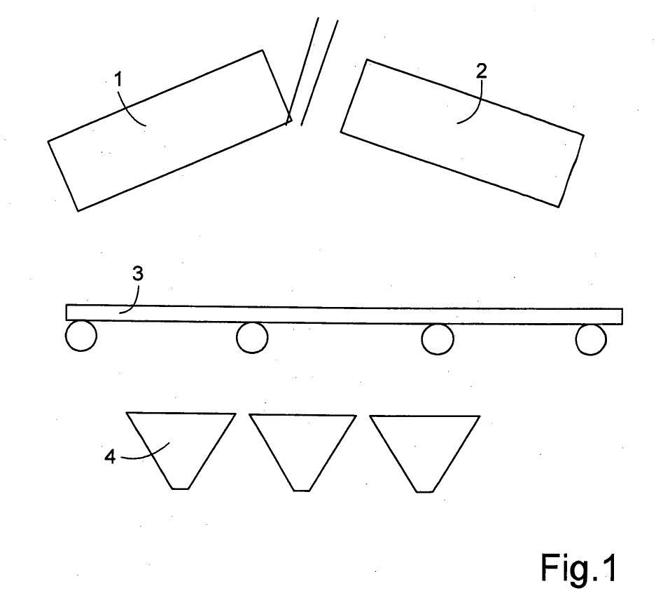

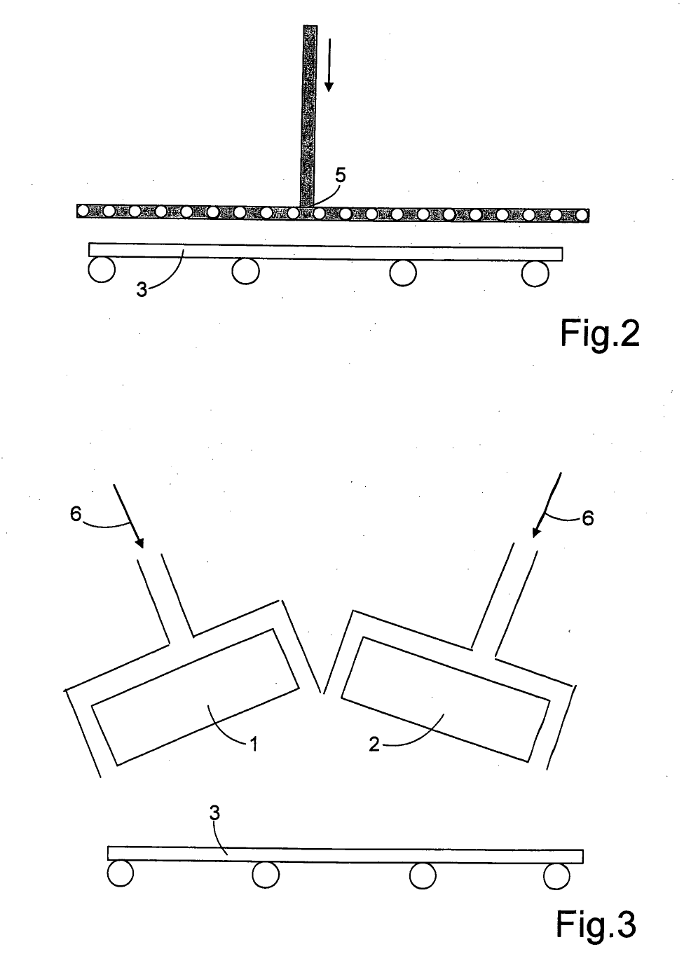

In one embodiment of the present invention, the magnetron sputtering system is equipped with an air lock to ensure constant process conditions in the coating chamber. The process chamber for the absorber layer may be provided with a double magnetron source, which is equipped with a copper target 1 and an indium target 2 of 4N purity as sputter sources. Substrates 3 are moved under the sputter sources including targets 1, 2, and are retained in position during coating (FIG. 1). In another embodiment, substrates 3 may also be moved along at low speed under the sputter sources including targets 1, 2. The growing layer is heated from behind substrate 3 by halogen lamps 4. The introduction of reactive gas 5 is via a gas shower near substrate 3 (FIG. 2). The introduction of inert gas 6 is effected directly at the sputter sources including targets 1, 2 (FIG. 3).

In the following, the process sequence is described in detail for an exemplary embodiment.

(1) Coating the substrate with molybdenum as a back contact, and subsequently introducing the substrate into the sputtering chamber through the air lock. The coating with molybdenum may be carried out in a DC sputtering system, or using an electron-beam vaporization source.

(2) Heating the substrate to 300° C. Coating the substrate with In+Cu in H₂S+Ar (reactive gas/inert gas) at a sputtering pressure of 1 Pa and an H₂S partial pressure of 0.3 Pa. In the process, the ratio of the sputter rate of Cu to that of In is 0.85. The first layer produced has a thickness of about 2 μm.

(2a) Alternatively: Heating the substrate to 300° C. Coating the substrate with indium+gallium+copper in H₂S+Ar at a sputtering pressure of 1 Pa and an H₂S partial pressure of 0.28 Pa. Sputtering rate ratios: Cu/In=0.85 and In/Ga=0.85. The thickness of the first layer produced is also about 2 μm.

(3) Heating the substrate to 420° C., while simultaneously coating the substrate with In+Cu in H₂S+Ar at a pressure of 1 Pa, at an H₂S partial pressure of 0.3 Pa, and at a Cu/In sputtering rate ratio of 1. The second layer produced has a thickness of about 1 μm. This step serves to recrystallize the first layer produced and to obtain the final ratio of elements. In this phase of the process, a negative bias voltage of 40 V is applied to the substrate in order to produce large crystallites, although the substrate temperature is as low as 420° C. The end point of this process step is determined by laser light scattering and pyrometry.

(3a) Alternatively: Heating the substrate to 500° C., while simultaneously coating the substrate with In+Cu in H₂S+Ar at a pressure of 1 Pa and a Cu/In sputtering rate ratio of 1.2. The thickness of the second layer produced is also about 1 μm. In this phase, the deposition is performed in the presence of an excess of copper so as to achieve a stoichiometric layer composition. In this alternative process step, no negative substrate bias voltage is needed. The end point of the process is determined by laser light scattering and pyrometry.

(4) Depositing an about 50 nm thick buffer layer by magnetron sputtering of In₂S₃ or Zn(O, S).

(4a) Alternatively: depositing a 50 nm thick CdS layer as the buffer layer by chemical bath deposition.

(4b) Alternatively: performing a KCN etching step to remove CuₓS phases segregated at the surface, and subsequently depositing a 50 nm thick CdS layer as the buffer layer by chemical bath deposition.

(4c) Alternatively: performing a KCN etching step to remove CuₓS phases segregated at the surface, and subsequently depositing a 50 nm thick buffer layer by magnetron sputtering of In₂S₃ or Zn(O, S).

(5) magnetron sputtering an about 1 μm thick ZnO/ZnO:AI layer as the front contact.

The implementation of process steps (1, 2, 2a, 3, 3a, 4, 5) describes a process for manufacturing a CuInS₂ solar cell at temperatures below 500° C. using magnetron sputtering processes and advantageously without chemical process steps. The implementation of process steps (1, 2, 2a, 3, 3a, 4a-4c, 5) describes a process for manufacturing a CuInS₂ solar cell, including two chemical process steps.

The present invention is not limited to the embodiments described herein; reference should be made to the appended claims.

### LIST OF REFERENCE NUMERALS

1 copper target (first sputter source)
2 indium target (second sputter source)
3 substrate
4 halogen lamp
5 reactive gas inlet
6 inert gas inlet

1-7. (canceled)

8. A method of reactive magnetron sputtering for large-area deposition of a chalcopyrite absorber layer for thin-film solar cells on a substrate, using at least one magnetron sputter source with at least one copper target, and using an inert gas and a chalcogen-containing reactive gas in a magnetron plasma, the method comprising:
introducing the chalcogen-containing reactive gas directly at the substrate;
setting the chalcogen-containing reactive gas fraction at 5 to 30% of the inert gas fraction in the magnetron plasma;
setting a sputtering pressure of between 1 and 2 Pa;
applying a negative bias voltage to the substrate;
exciting the magnetron plasma by radio frequency AC voltage above 6 MHz;
heating the substrate to a temperature between 350° C. and 500° C.; and
performing low-copper deposition by disposing different targets serially in the at least one magnetron sputter source and operating the targets at the same sputtering power, or by disposing same targets in the at least one magnetron sputter source and operating the targets at different sputtering powers so as to obtain stoichiometry gradients.

9. The method as recited in claim 8 wherein the introducing is performed by directly introducing the chalcogen-containing reactive gas parallel to the surface of the substrate.

10. The method as recited in claim 8 wherein no additional chemical steps are performed.

11. The method as recited in claim 8 further comprising selecting the targets so as to provide a graded band gap transition from a narrow-band chalcopyrite absorber layer to an adjacent buffer layer.

12. The method as recited in claim 8 wherein:
the chalcopyrite absorber layer includes CuInS₂ with a [In]/[Cu] ratio>1;
the inert gas includes argon;
the chalcogen-containing reactive gas includes H₂S; and
at least one of the targets includes indium.

13. The method as recited in claim 8 wherein:
the chalcopyrite absorber layer includes CuInSe₂ with a [In]/[Cu] ratio>1;
the inert gas includes argon;
the chalcogen-containing reactive gas includes H₂Se; and
at least one of the targets includes indium.

14. The method as recited in claim 8 further comprising:
performing process feedback using optical in situ-measurement; and
varying at least one of the magnetron sputtering power and the substrate bias voltage based on the measurement.

15. The method as recited in claim 14 wherein the optical in situ-measurement includes Raman spectroscopic phase analysis.
